(19) United States
(12) Patent Application Publication
(10) Pub. No.: US 2025/0270700 A1
(43) Pub. Date: Aug. 28, 2025

(54) SUBSTRATE PROCESSING APPARATUS

(71) Applicant: TOKYO ELECTRON LIMITED, Tokyo (JP)

(72) Inventors: Nobuhiro MATSUYAMA, Iwate (JP); Koichi SHIMADA, Iwate (JP); Tomoshi TANIYAMA, Iwate (JP); Takashi YOSHIDA, Iwate (JP)

(21) Appl. No.: 19/057,905

(22) Filed: Feb. 19, 2025

(30) Foreign Application Priority Data
Feb. 22, 2024 (JP) 2024-025077

(51) Int. Cl. C23C 16/455; C23C 16/44; H01L 21/67

(52) U.S. Cl. CPC C23C 16/45578; C23C 16/4412; H01L 21/67017

(57) ABSTRACT

A substrate processing apparatus includes: a reaction tube; a gas introducer configured to introduce a gas into the reaction tube; a gas exhauster configured to exhaust the gas introduced into the reaction tube; and a housing configured to accommodate the reaction tube, the gas introducer, and the gas exhauster, wherein the gas introducer includes a gas introduction duct installed at an outer wall of the reaction tube, and wherein the gas introduction duct extends up to above an upper surface of the reaction tube to pass through the housing.

### CROSS-REFERENCE TO RELATED APPLICATION

This application is based upon and claims the benefit of priority from Japanese Patent Application No. 2024-025077, filed on Feb. 22, 2024, the entire contents of which are incorporated herein by reference.

### TECHNICAL FIELD

The present disclosure relates to a substrate processing apparatus.

### BACKGROUND

A batch-type substrate processing apparatus configured to collectively perform a processing on a plurality of substrates is known (e.g., see Patent Document 1). In the substrate processing apparatus described in Patent Document 1, a gas supply area is provided in an outer wall of a reaction tube.

### PRIOR ART DOCUMENTS

### Patent Documents

Patent Document 1: International Publication No. 2015/041376

### SUMMARY

According to one embodiment of the present disclosure, a substrate processing apparatus includes: a reaction tube; a gas introducer configured to introduce a gas into the reaction tube; a gas exhauster configured to exhaust the gas introduced into the reaction tube; and a housing configured to accommodate the reaction tube, the gas introducer, and the gas exhauster, wherein the gas introducer includes a gas introduction duct installed at an outer wall of the reaction tube, and wherein the gas introduction duct extends up to above an upper surface of the reaction tube to pass through the housing.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a perspective view 1 illustrating a substrate processing apparatus according to an embodiment.

FIG. 2 is a perspective view 2 illustrating the substrate processing apparatus according to the embodiment.

FIG. 3 is a vertical cross-sectional view illustrating the substrate processing apparatus according to the embodiment.

FIG. 4 is a horizontal cross-sectional view 1 illustrating the substrate processing apparatus according to the embodiment.

FIG. 5 is a horizontal cross-sectional view 2 illustrating the substrate processing apparatus according to the embodiment.

FIG. 6 is a view illustrating an example of an exhaust duct.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limiting exemplary embodiments are described with reference to the accompanying drawings. Throughout the drawings, the same or corresponding members or components are denoted by the same or corresponding reference numerals, and duplicated descriptions are omitted.

### (Substrate Processing Apparatus)

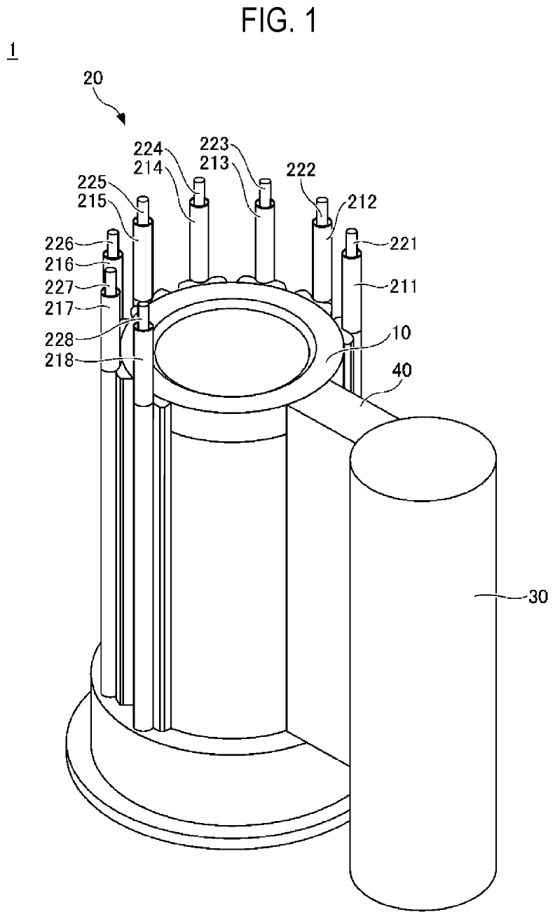

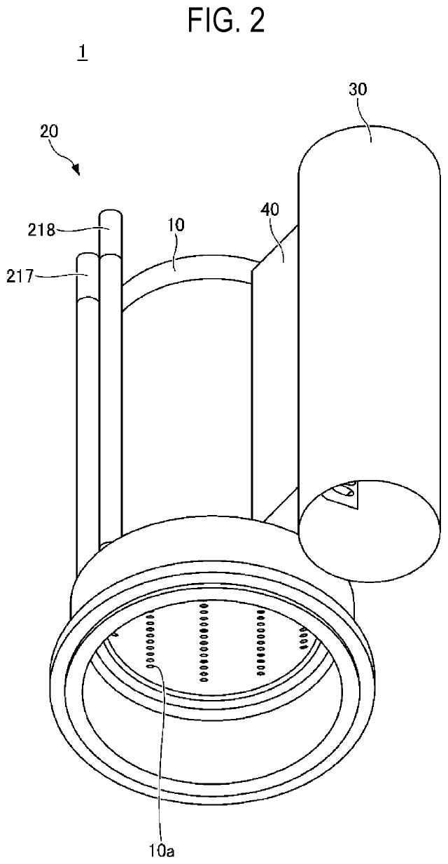

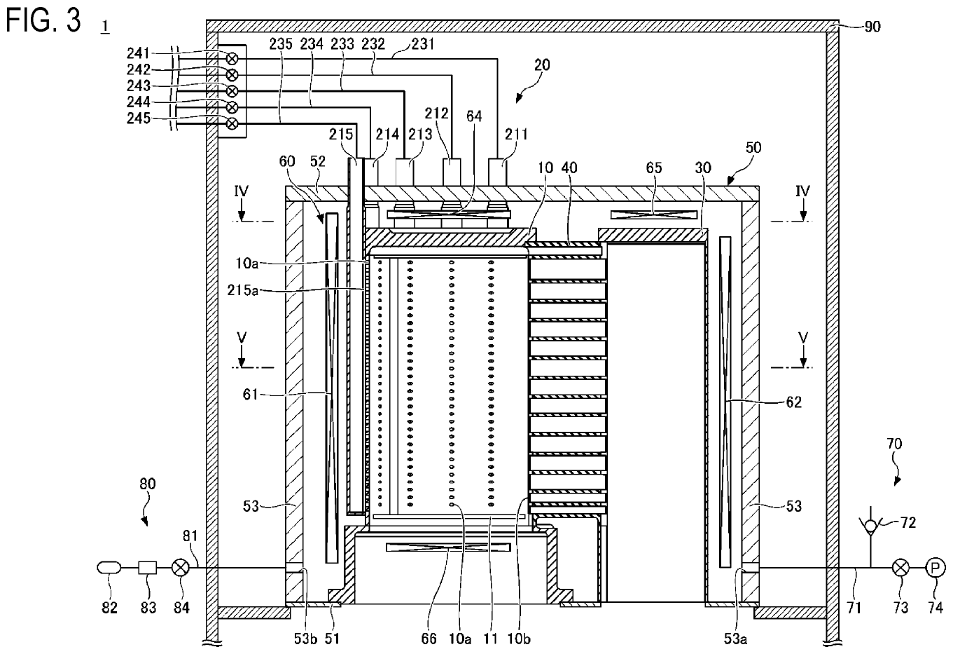

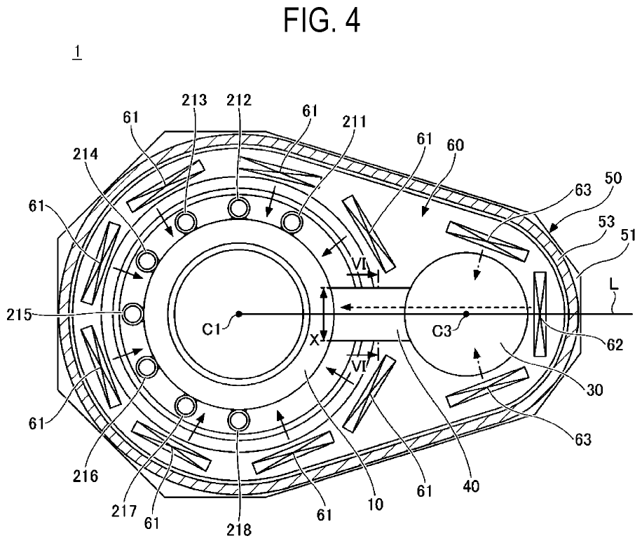

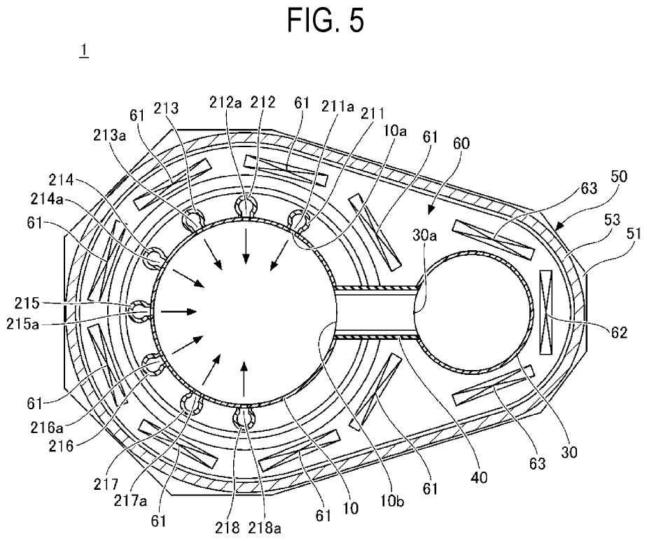

A substrate processing apparatus 1 according to an embodiment is described with reference to FIGS. 1 to 5. FIG. 1 is a perspective view illustrating the substrate processing apparatus 1 according to the embodiment, and is a view of the substrate processing apparatus 1 as obliquely viewed from above. FIG. 2 is a perspective view illustrating the substrate processing apparatus 1 according to the embodiment, and is a view of the substrate processing apparatus 1 as obliquely viewed from below. FIG. 3 is a vertical cross-sectional view illustrating the substrate processing apparatus 1 according to the embodiment. FIG. 4 is a horizontal cross-sectional view illustrating the substrate processing apparatus 1 according to the embodiment, and illustrates a cross-section taken along line IV-IV arrow direction in FIG. 3. FIG. 5 is a horizontal cross-sectional view illustrating the substrate processing apparatus 1 according to the embodiment, and illustrates a cross-section taken along line V-V arrow direction in FIG. 3.

The substrate processing apparatus 1 is a batch-type apparatus configured to collectively perform various processings on a plurality of substrates W. The various processings include a film formation processing of forming a film on the substrate W by, for example, atomic layer deposition (ALD) or chemical vapor deposition (CVD). The various processings may include an etching processing of removing a film formed on the substrate W.

The substrate processing apparatus 1 includes a reaction tube 10, a gas introducer 20, a vacuum pipe 30, an exhaust duct 40, a housing 50, a heating part 60, a depressurizer 70, a pressurizer 80, and an apparatus housing 90. In FIGS. 1 and 2, illustration of the housing 50, the heating part 60, the depressurizer 70, the pressurizer 80, and the apparatus housing 90 is omitted. The reaction tube 10, the vacuum pipe 30, and the exhaust duct 40 are bonded to each other by, for example, welding or the like, to be configured as a single body. The reaction tube 10, the vacuum pipe 30, and the exhaust duct 40 are made of, for example, quartz.

The reaction tube 10 has a cylindrical shape with a ceiling, of which a lower end is opened. An introduction opening 10a and an exhaust opening 10b are provided in an outer wall of the reaction tube 10.

The introduction opening 10a passes through the outer wall of the reaction tube 10. The introduction opening 10a is provided at a position at which each of gas introduction ducts 211 to 218 to be described later is installed along a circumferential direction of the reaction tube 10. The introduction opening 10a is provided in plurality along a vertical direction from an upper end vicinity to a lower end vicinity of the reaction tube 10 at each position along the circumferential direction of the reaction tube 10. In this case, it is easy to evenly supply gas in a range from an upper end to a lower end in the reaction tube 10.

The exhaust opening 10b passes through the outer wall of the reaction tube 10. The exhaust opening 10b is proved at a position different from that of the introduction opening 10a in the circumferential direction of the reaction tube 10. The exhaust opening 10b is provided at a position at which the exhaust duct 40 is installed in the circumferential direction of the reaction tube 10. The exhaust opening 10b is a rectangular opening extending along the vertical direction from the upper end vicinity to the lower end vicinity of the reaction tube 10. In this case, it is easy to evenly exhaust gas in a range from the upper end to the lower end in the reaction tube 10.

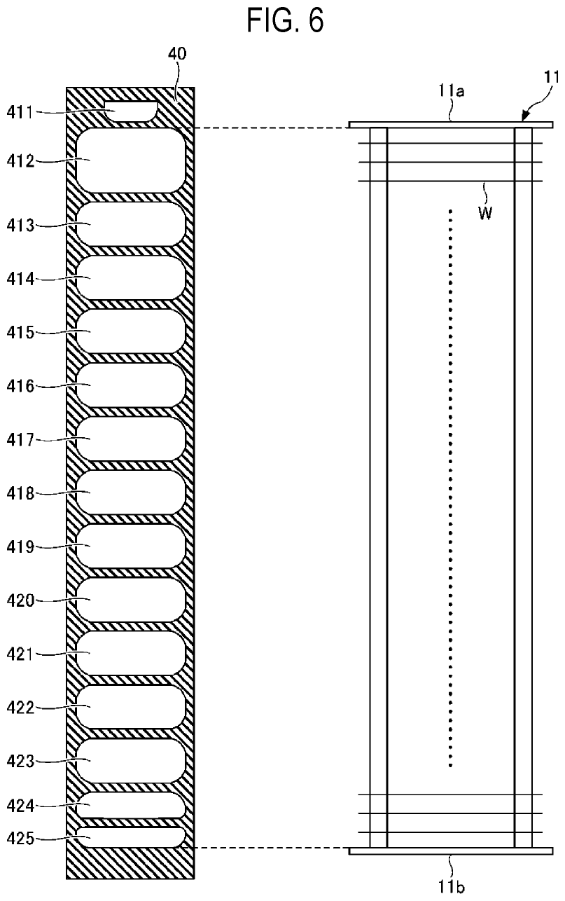

A lower end opening of the reaction tube 10 is airtightly covered by a cover body (not illustrated). The cover body is made of, for example, a metal such as stainless steel. A substrate holder 11 (FIG. 3) is accommodated in the reaction tube 10. The substrate holder 11 holds a plurality of substrates W (FIG. 6) by horizontally arranging the plurality of substrates W in multi-stage along the vertical direction. The number of substrates W is not limited, but is, for example, 25 to 200. In FIG. 3, illustration of the substrate W is omitted. The substrate holder 11 is made of, for example, quartz.

The gas introducer 20 includes the gas introduction duct 211 to 218, nozzles 221 to 228, gas introduction pipes 231 to 238, and opening/closing valves 241 to 248. In FIG. 3, the gas introduction pipes 231 to 235 and the opening/closing values 241 to 245 are illustrated.

The gas introduction ducts 211 to 218 are provided along the circumferential direction of the reaction tube 10. The gas introduction ducts 211 to 218 are provided to be spaced apart from each other in the circumferential direction of the reaction tube 10. In this case, heat influence from the adjacent gas introduction ducts 211 to 218 may be reduced. Accordingly, temperature lowering in the gas introduction ducts 211 to 218 may be suppressed, and occurrence of particles may be suppressed. The gas introduction ducts 211 to 218 are radially provided at intervals in the circumferential direction of the reaction tube 10. In this case, as indicated by arrows in FIG. 5, a gas, such as a raw material gas, a reaction gas, an etching gas, or a purge gas, may be supplied into the reaction tube 10 from at a plurality of positions (various directions) in the circumferential direction of the reaction tube 10. Therefore, an in-plane shape of film formation or etching may be easily adjusted. For example, by adjusting a supply position of the gas or a supply amount of the gas, a stay time or gas concentration distribution of the gas supplied onto a surface of the substrate W may be adjusted. Therefore, the in-plane shape of film formation or etching is controlled more easily than when the gas is flowed in a single direction. The gas introduction ducts 211 to 218 are, for example, sequentially provided counterclockwise from the exhaust opening 10b.

The gas introduction ducts 211 to 218 are installed at the outer wall of the reaction tube 10. In this case, distances from the gas introduction ducts 211 to 218 to the substrate W are shortened. Therefore, unnecessary thermal decomposition of gas may be suppressed. Further, when the gas introduction ducts 211 to 218 are installed at the outer wall of the reaction tube 10, it is unnecessary to place the nozzles 221 to 228 inside the reaction tube 10. Therefore, a space between an outer circumferential end of the substrate W and an inner wall of the reaction tube 10 may be narrowed, and thus a flow of gas into the corresponding space may be suppressed. As a result, supply efficiency of the gas between the substrates W adjacent in the vertical direction may be improved. Furthermore, when the gas introduction ducts 211 to 218 are installed at the outer wall of the reaction tube 10, it is unnecessary to form a nozzle chamber configured to accommodate the nozzles 221 to 228 by making a sidewall of the reaction tube 10 protrude outward in a diameter direction. The gas introduction ducts 211 to 218 are integrally configured with, for example, the reaction tube 10. The gas introduction ducts 211 to 218 are made of, for example, quartz.

The gas introduction ducts 211 to 218 have a tubular shape of which a lower end is closed and an upper end is opened. The upper end of each of the gas introduction ducts 211 to 218 extends up to above an upper surface of the reaction tube 10 to pass through the housing 50. In this case, an upper space of the housing 50 may be used as a space in which the gas introduction pipes 231 to 238 or the opening/closing valves 241 to 248 are installed. Therefore, a pipe distance from the opening/closing valves 241 to 248 to the reaction tube 10 may be shortened. Further, a shape of the gas introduction pipes 231 to 238 may be simplified. Gas holes 211a to 218a (FIG. 5) are provided at positions of the gas introduction ducts 211 to 218 facing the reaction tube 10.

Each of the gas holes 211a to 218a has, for example, a rectangular shape extending along the vertical direction from the upper end vicinity to the lower end vicinity of the reaction tube 10. Each of the gas holes 211a to 218a extends, for example, from above an uppermost introduction opening 10a to below a lowermost introduction opening 10a. A gas flowing into the gas introduction ducts 211 to 218 is ejected into the reaction tube 10 from the gas holes 211a to 218a.

The gas introduction duct 211 is provided at an angle of smaller than 90 degrees counterclockwise from the exhaust duct 40 in the circumferential direction of the reaction tube 10. The gas introduction duct 212 is provided at an angle of 90 degrees counterclockwise from the exhaust duct 40 in the circumferential direction of the reaction tube 10. The gas introduction ducts 213 and 214 are each provided at an angle of larger than 90 degrees and smaller than 180 degrees counterclockwise from the exhaust duct 40. The gas introduction duct 215 is provided at an angle of 180 degrees counterclockwise from the exhaust duct 40 in the circumferential direction of the reaction tube 10. That is, the gas introduction duct 215 is provided at a position facing the exhaust duct 40. The gas introduction ducts 216 and 217 are each provided at an angle of larger than 180 degrees and smaller than 270 degrees counterclockwise from the exhaust duct 40. The gas introduction duct 218 is provided at an angle of 270 degrees counterclockwise from the exhaust duct 40. That is, the gas introduction duct 218 is provided at a position facing the gas introduction duct 212.

The nozzles 221 to 228 are detachably inserted into the gas introduction ducts 211 to 218. In this case, optimum nozzles 221 to 228 according to a type of processing may be used by changing a shape or the like of the nozzles 221 to 228 according to the type of processing. Inner surfaces of the gas introduction ducts 211 to 218 have a shape according to outer surfaces of the nozzles 221 to 228, and gaps are provided between the inner surfaces of the gas introduction ducts 211 to 218 and the outer surfaces of the nozzles 221 to 228. In this case, a volume of a space between the gas introduction ducts 211 to 218 and the nozzles 221 to 228 may be reduced. Therefore, stay of the gas in the corresponding space is suppressed, and thus the supply efficiency of gas onto the substrate W may be improved. Further, since a surface area in contact with the gas is decreased, occurrence of particles in the corresponding space may be suppressed. Therefore, the corresponding space may be easily cleaned. In a cross-section orthogonal to a length direction of the nozzles 221 to 228, the inner surfaces of the gas introduction ducts 211 to 218 are, for example, circular, and the outer surfaces of the nozzles 221 to 228 are, for example circular. In the cross-section orthogonal to the length direction of the nozzles 221 to 228, the inner surfaces of the gas introduction ducts 211 to 218 may be elliptical, and the outer surfaces of the nozzles 221 to 228 may be elliptical.

The nozzles 221 to 228 are provided with gas ejection holes (not illustrated). The gas ejection holes are provided at, for example, portions of tube walls of the nozzles 221 to 228, which are inserted into the gas introduction ducts 211 to 218. Upper ends of the nozzles 221 to 228 are connected to gas sources (not illustrated) through the corresponding gas introduction pipes 231 to 238. Gases from the gas sources are introduced into the nozzles 221 to 228 from the upper ends of the nozzles 221 to 228, to be ejected into the reaction tube 10 through the gas ejection holes, the gas holes 211a to 218a, and the introduction opening 10a. In FIGS. 2 to 5, illustration of the nozzles 221 to 228 is omitted.

The nozzles 221 to 228 may not be provided. In this case, the upper ends of the gas introduction ducts 211 to 218 are connected to the gas sources through the corresponding gas introduction pipes 231 to 238. The gases from the gas sources are introduced into the gas introduction ducts 211 to 218 from the upper ends of the gas introduction ducts 211 to 218, to be ejected into the reaction tube 10 through the gas holes 211a to 218a. For example, when a gas such as a hexachlorodisilane (HCD) gas or a dichlorosilane (DCS) gas, which is easily thermal-decomposed, is used, it is unnecessary to provide the nozzles 221 to 228.

The gas introduction pipes 231 to 238 are provided in the upper space of the housing 50. One ends of the gas introduction pipes 231 to 238 are connected to the corresponding gas introduction ducts 211 to 218 or the corresponding nozzles 221 to 228, and the other ends of the gas introduction pipes 231 to 238 extend up to an outside of the apparatus housing 90 by passing through the apparatus housing 90. The gas introduction pipes 231 to 238 are provided with the opening/closing valves 241 to 248. The gas introduction pipes 231 to 238 may be provided with a flow rate controller such as a mass flow controller.

The opening/closing valves 241 to 248 are provided in the upper space of the housing 50. The opening/closing valves 241 to 248 are provided in the middle of the corresponding gas introduction pipes 231 to 238. The opening/closing valves 241 to 248 are installed at an inner wall of the apparatus housing 90. The opening/closing valves 241 to 248 are valves configured to switch on and off of the flow of gas.

The vacuum pipe 30 has a cylindrical shape with a ceiling, of which a lower end is opened. The vacuum pipe 30 is provided to be spaced apart from the reaction tube 10. At an outer wall of the vacuum pipe 30, an opening 30a (FIG. 5) is provided at a same position as the exhaust duct 40 along a circumferential direction of the vacuum pipe 30. The opening 30a is a rectangular opening extending along the vertical direction from an upper end vicinity to a lower end vicinity of the vacuum pipe 30. A length of the opening 30a in the vertical direction may be equal to a length of the exhaust opening 10b in the vertical direction. An axis of the vacuum pipe 30 may be parallel to an axis of the reaction tube 10. A lower end of the vacuum pipe 30 is connected to an exhaust apparatus (not illustrated) such as a vacuum pump through a pipe (not illustrated). A flow path cross-sectional area of the vacuum pipe 30 may be equal to or larger than a flow path cross-sectional area of the exhaust duct 40. In this case, an exhaust flow velocity in the vertical direction becomes uniform, and thus a uniform laminar flow is formed in the vertical direction. Therefore, an inter-plane uniformity for film formation or etching improves.

The exhaust duct 40 connects the reaction tube 10 and the vacuum pipe 30. The exhaust duct 40 allows an inside of the reaction tube 10 and an inside of the vacuum pipe 30 to communicate with each other. One end of the exhaust duct 40 is connected to the outer wall of the reaction tube 10 to cover the exhaust opening 10b, and the other end of the exhaust duct 40 is connected to the outer wall of the vacuum pipe 30 to cover the opening 30a. In this case, a length X occupied by the exhaust duct 40 in the circumferential direction of the reaction tube 10 is shortened as compared with when the vacuum pipe 30 is directly connected to the reaction tube 10 without being provided with the exhaust duct 40. Therefore, a length with which the gas introduction ducts 211 to 218 may be installed in the circumferential direction of the reaction tube 10 is lengthened. Accordingly, the number of the gas introduction ducts 211 to 218 provided on the outer wall of the reaction tube 10 may be increased. The exhaust duct 40 may be divided in plurality in the vertical direction. In this case, a flow of gas toward the vacuum pipe 30 from the inside of the reaction tube 10 is rectified. For this reason, uniformity of a gas flow at another position in the vertical direction inside the reaction tube 10 is improved.

The housing 50 accommodates therein the reaction tube 10, the gas introducer 20, a vacuum pipe 30, the exhaust duct 40, and the heating part 60. The housing 50 accommodates the heating part 60 including a heater, and therefore, is referred to as a heater shell. The housing 50 includes a bottom portion 51, a ceiling portion 52, and a side portion 53. The bottom portion supports the reaction tube 10 and the vacuum pipe 30. The ceiling portion 52 is provided above the upper surface of the reaction tube 10 and an upper surface of the vacuum pipe 30. The ceiling portion 52 covers the upper surface of the reaction tube 10 and the upper surface of the vacuum pipe 30. The side portion 53 is provided at a periphery of the reaction tube 10, the gas introducer 20, the vacuum pipe 30, and the exhaust duct 40. The side portion 53 covers the periphery of the reaction tube 10, the gas introducer 20, the vacuum pipe 30, and the exhaust duct 40. A lower end of the side portion 53 is connected to the bottom portion 51, and an upper end of the side portion 53 is connected to the ceiling portion 52. The bottom portion 51, the ceiling portion 52, and the side portion 53 may be configured as separate bodies. The bottom portion 51, the ceiling portion 52, and the side portion 53 may be configured as a single body.

The heating part 60 is provided inside the housing 50. The heating part 60 includes a first side heater 61, a second side heater 62, a third side heater 63, a first ceiling heater 64, a second ceiling heater 65, and a lower heater 66. Each of the first side heater 61, the second side heater 62, the third side heater 63, the first ceiling heater 64, the second ceiling heater 65, and the lower heater 66 is, for example, a carbon wire heater. In this case, a temperature of the substrate W accommodated in the reaction tube 10 may be increased or decreased rapidly.

The first side heater 61 is provided in plurality at the periphery of the reaction tube 10. The plurality of first side heaters 61 are radially provided at intervals in the circumferential direction of the reaction tube 10. Each first side heater 61 is provided at a position different from that of the exhaust duct 40 in the circumferential direction of the reaction tube 10. Each first side heater 61 may be divided in plurality in the vertical direction. In this case, the first side heaters 61 divided into plurality are independently controlled, so that temperatures in the vertical direction may be independently adjusted. As indicated by a solid line arrow in FIG. 4, the first side heaters 61 heat the substrate W accommodated in the reaction tube 10 from the outside of the reaction tube 10 by thermal radiation.

The second side heater 62 is provided at a position different from that of the first side heater 61 in the circumferential direction of the reaction tube 10. The second side heater 62 is provided at a position different from those of the plurality of gas introduction ducts 211 to 218 in the circumferential direction of the reaction tube 10. The second side heater 62 is provided at a position including a same position as the exhaust duct 40 in the circumferential direction of the reaction tube 10. Since the exhaust duct 40 is provided at the periphery of the reaction tube 10 at the same position as the exhaust duct 40 in the circumferential direction of the reaction tube 10, it is not possible to locate the second side heater 62. Therefore, the second side heater 62 is provided at the periphery of the vacuum pipe 30. That is, the second side heater 62 is provided at a position at which a distance of the second side heater 62 from a center C1 of the reaction tube 10 is longer than a distance of the first side heater 61 from the center C1 of the reaction tube 10. For example, in a plane view, the second side heater 62 is provided, along a virtual half line L extending by passing through a center C3 of the vacuum pipe 30, using the center C1 of the reaction tube 10 as a starting point. The second side heater 62 may be divided in plurality in the vertical direction. In this case, the second side heaters 62 divided into plurality are independently controlled, so that temperatures in the vertical direction may be independently adjusted. As indicated by a dashed line arrow in FIG. 4, the second side heater 62 heats the substrate W accommodated in the reaction tube 10 while heating the vacuum pipe 30 and the exhaust duct 40 by thermal radiation. Accordingly, the substrate W accommodated in the reaction tube 10 is heated in all directions at the periphery of the reaction tube 10 by the first side heater 61 and the second side heater 62. Therefore, temperature uniformity in a substrate plane is improved.

The third side heater 63 is provided in plurality at the periphery of the vacuum pipe 30. The plurality of third side heaters 63 are provided at intervals in the circumferential direction of the vacuum pipe 30. Each third side heater 63 is provided at a position different from that of the second side heater 62 in the circumferential direction of the vacuum pipe 30. In a plane view, each third side heater 63 is provided, not along the virtual half line L. Each third side heater 63 may be divided in plurality in the vertical direction. In this case, the third side heaters 63 divided into plurality are independently controlled, so that temperatures in the vertical direction may be independently adjusted. As indicated by an alternate long and short dash line arrow in FIG. 4, the third side heater 63 heats the vacuum pipe 30.

The first ceiling heater 64 is provided between the upper surface of the reaction tube 10 and the ceiling portion 52 of the housing 50. The first ceiling heater 64 heats the substrate W accommodated in the reaction tube 10 from above the reaction tube 10 by thermal radiation. One first ceiling heater 64 may be provided, and two or more first ceiling heaters 64 may be provided.

The second ceiling heater 65 is provided between the upper surface of the vacuum pipe 30 and the ceiling portion 52 of the housing 50. The second ceiling heater 65 heats the vacuum pipe 30 from above the vacuum pipe 30 by thermal radiation. One second ceiling heater 65 may be provided, and two or more second ceiling heaters 65 may be provided.

The lower heater 66 is provided in plurality at a periphery of a lower portion of the reaction tube 10. The plurality of lower heaters 66 are radially provided at intervals in the circumferential direction of the reaction tube 10. The lower heater 66 is provide below the substrate holder 11. The lower heater 66 heats the lower portion of the reaction tube 10 by thermal radiation, and suppresses the radiation of heat from the lower end opening of the reaction tube 10.

The depressurizer 70 depressurizes an inside of the housing 50. The depressurizer 70 includes a pipe 71, a safety valve 72, an opening/closing valve 73, and a vacuum pump 74.

The pipe 71 is connected to a port 53a provided in the side portion 53 of the housing 50. The pipe 71 extends up to the outside of the apparatus housing 90 by passing through the side portion 53 and the apparatus housing 90. On the pipe 71, the safety valve 72, the opening/closing valve 73, and the vacuum pump 74 are provided sequentially from a side of the housing 50. The safety valve 72, the opening/closing valve 73, and the vacuum pump 74 are provided, for example, outside the apparatus housing 90. The safety valve 72, the opening/closing valve 73, and the vacuum pump 74 may be provided inside the housing 50 and outside the apparatus housing 90.

A state of the safety valve 72 is changed from a closed state to an open state when an internal pressure of the housing 50 exceeds a set pressure, so that the safety valve 72 maintains the internal pressure of the housing 50 to the set pressure or lower.

The opening/closing valve 73 is a valve configured to switch on and off a flow of gas.

The vacuum pump 74 depressurizes the inside of the housing 50 through the pipe 71.

When a state of the opening/closing valve 73 becomes an open state, the inside of the housing 50 is depressurized by the vacuum pump 74. In the state in which the inside of the housing 50 is depressurized, movement of heat by convection is suppressed. Accordingly, heat transfer to the outside of the housing 50 is suppressed, and thus the upper space of the housing 50 may be used as a space in which the opening/closing valves 241 to 248 are installed. Further, no insulator is required, and thus a distance between the reaction tube 10 and the housing 50 may be shortened. Therefore, a distance from the opening/closing valves 241 to 248 to the substrate may be shortened, and thus control performance of gas is improved.

Furthermore, when each of the side heaters (the first side heater 61, the second side heater 62, and the third side heater 63) is divided in plurality in the vertical direction, each heater is not influenced by the other heaters in the vertical direction since there is no influence of convection inside the housing 50. Therefore, inter-plane (vertical direction) temperature control performance is improved. Accordingly, it is easy to selectively heat only the lower portion of the reaction tube 10, only a central portion of the reaction tube 10, or only an upper portion of the reaction tube 10.

The pressurizer 80 allows the inside of the depressurized housing 50 to return to the atmospheric pressure. The pressurizer 80 includes a pipe 81, a gas source 82, a flow rate controller 83, and an opening/closing valve 84.

The pipe 81 is connected to a port 53b provided in the side portion 53 of the housing 50. The pipe 81 extends up to the outside of the apparatus housing 90 by passing through the side portion 53 and the apparatus housing 90. On the pipe 81, the gas source 82, the flow rate controller 83, and the opening/closing valve 84 are provided sequentially toward a downstream from an upstream of a flow direction of gas. The gas source 82, the flow rate controller 83, and the opening/closing valve 84 are provided, for example, outside the apparatus housing 90. The gas source 82, the flow rate controller 83, and the opening/closing valve 84 may be provided inside the housing 50 and outside the apparatus housing 90.

The gas source 82 is a supply source of, for example, an inert gas. The inert gas is, for example, a nitrogen gas. The inert gas may be an argon gas.

The flow rate controller 83 controls a flow of gas flowing in the pipe 81. The flow rate controller 83 may be, for example, a mass flow controller.

The opening/closing valve 84 is a valve configured to switch on and off the flow of gas.

When a state of the opening/closing valve 84 becomes an open state, the gas from the gas source 82 is controlled in flow rate by the flow rate controller 83, and the gas of which the flow rate is controlled is supplied to the inside of the housing 50. Accordingly, the inside of the depressurized housing 50 returns to the atmospheric pressure.

The apparatus housing 90 surrounds the housing 50. The apparatus housing 90 covers the whole of the housing 50. The apparatus housing 90 supports the bottom portion 51 of the housing 50.

As described above, according to the substrate processing apparatus 1 according to the embodiment, the gas introduction ducts 211 to 218 are installed at the outer wall of the reaction tube 10, and extend above the upper surface of the reaction tube 10 to pass through the housing 50. Accordingly, the supply efficiency of gas between the substrates W may be improved while suppressing unnecessary thermal decomposition of the gas. Further, since it is possible to supply the gas from at a plurality of positions (various directions) in the circumferential direction of the reaction tube 10, the in-plane shape of film formation or etching may be easily adjusted.

### (Exhaust Duct)

An example of the exhaust duct 40 is described with reference to FIG. 6. FIG. 6 is a view illustrating the example of the exhaust duct 40. The left drawing in FIG. 6 illustrates a cross-section taken along line IV-IV arrow direction in FIG. 4, and the right drawing in FIG. 6 illustrates the substrate holder 11.

The exhaust duct 40 includes a plurality of divided flow paths 411 to 425. The plurality of divided flow paths 411 to 425 are provided at intervals along the vertical direction.

The divided flow path 411 is provided in a height region above a ceiling plate 11a of the substrate holder 11. The divided flow path 411 mainly exhausts a gas flowing along an upper surface of the ceiling plate 11a. The divided flow paths 412 and 425 are provided at a height region (hereinafter, referred to as a “substrate holding region”) below the ceiling plate 11a of the substrate holder 11 and above a bottom plate 11b of the substrate holder 11. The divided flow paths 412 to 425 mainly exhaust a gas flowing along the surface of the substrate W held by the substrate holder 11.

The divided flow paths 413 to 423 have, for example, a same flow path cross-sectional area. In this case, it is easy to improve uniformity of exhaust amounts in the vertical direction in the substrate holding region.

A flow path cross-sectional area of the divided flow path 411 is smaller than, for example, that of each of the divided flow paths 413 to 423. In this case, an amount of the gas flowing along the upper surface of the ceiling plate 11a may be decreased, and an amount of the gas flowing in the substrate holding region may be increased. Therefore, the gas introduced into the reaction tube 10 from the gas introducer 20 may be efficiently used. A flow path cross-sectional area of the divided flow path 412 may be larger than that of each of the divided flow paths 413 to 423. Flow path cross-sectional areas of the divided flow paths 424 and 425 may be smaller than that of each of the divided flow paths 413 to 423.

According to the present disclosure in some embodiments, it is possible to improve supply efficiency of a gas between substrates.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a reaction tube;
a gas introducer configured to introduce a gas into the reaction tube;
a gas exhauster configured to exhaust the gas introduced into the reaction tube; and
a housing configured to accommodate the reaction tube, the gas introducer, and the gas exhauster,
wherein the gas introducer includes a gas introduction duct installed at an outer wall of the reaction tube, and
wherein the gas introduction duct extends up to above an upper surface of the reaction tube to pass through the housing.

2. The substrate processing apparatus of claim 1, wherein the gas introduction duct includes a plurality of gas introduction ducts along a circumferential direction of the reaction tube.

3. The substrate processing apparatus of claim 2, wherein the plurality of gas introduction ducts are provided to be spaced apart from each other in the circumferential direction of the reaction tube.

4. The substrate processing apparatus of claim 1, wherein the gas introducer includes a nozzle detachably inserted into the gas introduction duct, and
wherein the nozzle introduces the gas into the reaction tube.

5. The substrate processing apparatus of claim 4, wherein an inner surface of the gas introduction duct has a shape according to an outer surface of the nozzle, and
wherein a gap is provided between the inner surface of the gas introduction duct and the outer surface of the nozzle.

6. The substrate processing apparatus of claim 5, further comprising:
an apparatus housing configured to surround the housing,
wherein the gas introducer includes:
a gas introduction pipe connected to the gas introduction duct; and
an opening/closing valve provided in the gas introduction pipe,
wherein the opening/closing valve is installed at the apparatus housing.
